(19) United States
(12) Patent Application Publication
(10) Pub. No.: US 2026/0110765 A1
(43) Pub. Date: Apr. 23, 2026

(54) MAGNETIC RESONANCE IMAGING APPARATUS AND METHOD

(71) Applicant: Canon Medical Systems Corporation, Otawara-shi (JP)

(72) Inventors: Shuki MARUYAMA, Nasushiobara Tochigi (JP); Hidenori TAKESHIMA, Tokyo (JP)

(73) Assignee: Canon Medical Systems Corporation, Otawara-shi (JP)

(21) Appl. No.: 19/361,346

(22) Filed: Oct. 17, 2025

(30) Foreign Application Priority Data
Oct. 17, 2024 (JP) 2024-181914

(51) Int. Cl. G01R 33/54; G01R 33/56; G01R 33/563

(52) U.S. Cl. CPC G01R 33/543; G01R 33/5608; G01R 33/563

(57) ABSTRACT

A magnetic resonance imaging apparatus according to an embodiment includes a collection unit, a generation unit, a calculation unit, and a determination unit. The collection unit collects k-space data by executing first magnetic resonance (MR) image capturing on a subject. The generation unit generates morphological image data representing a morphology of the subject based on the k-space data. The calculation unit calculates phase distribution data representing a spatial distribution including phase information based on at least the morphological image data. The determination unit determines necessity of a change of second MR image capturing following the first MR image capturing based on the phase distribution data.

### CROSS-REFERENCE TO RELATED APPLICATIONS

This application is based upon and claims the benefit of priority from Japanese Patent Application No. 2024-181914, filed Oct. 17, 2024, the entire contents of which are incorporated herein by reference.

### FIELD

Embodiments described herein relate generally to a magnetic resonance imaging apparatus and a method.

### BACKGROUND

There is a technique for providing support information for supporting review of parameters and the like related to second image capturing based on quality of data collected in first image capturing. However, the technique is premised on X-ray computed tomography (CT) image capturing, and does not consider magnetic field homogeneity that affects quality of data collected by magnetic resonance (MR) image capturing.

### BRIEF DESCRIPTION OF THE DRAWINGS

FIG. 1 is a diagram illustrating a configuration example of a magnetic resonance imaging apparatus according to the present embodiment;

FIG. 2 is a diagram illustrating a generation process of a phase distribution estimation model according to the present embodiment;

FIG. 3 is a diagram illustrating an example of inputs and an output of a phase distribution estimation model;

FIG. 4 is a diagram illustrating another example of inputs and an output of the phase distribution estimation model;

FIG. 5 is a diagram illustrating another example of inputs and an output of the phase distribution estimation model;

FIG. 6 is a diagram illustrating another example of inputs and an output of the phase distribution estimation model;

FIG. 7 is a diagram illustrating a typical flow of a magnetic resonance (MR) examination executed by the magnetic resonance imaging apparatus according to the present embodiment;

FIG. 8 is a diagram illustrating an example of a display screen of a change recommended condition;

FIG. 9 is a diagram illustrating a typical flow of an MR examination executed by the magnetic resonance imaging apparatus according to a first example;

FIG. 10 is a diagram illustrating a typical flow of an MR examination executed by the magnetic resonance imaging apparatus according to a second example;

FIG. 11 is a diagram illustrating a generation process of a phase distribution estimation model according to the second example; and

FIG. 12 is a diagram illustrating a typical flow of an MR examination executed by the magnetic resonance imaging apparatus according to a third example.

### DETAILED DESCRIPTION

A magnetic resonance imaging apparatus according to an embodiment includes a collection unit, a generation unit, a calculation unit, and a determination unit. The collection unit collects k-space data by executing first magnetic resonance (MR) image capturing on a subject. The generation unit generates morphological image data representing a morphology of the subject based on the k-space data. The calculation unit calculates phase distribution data representing a spatial distribution including phase information based on at least the morphological image data. The determination unit determines necessity of a change of second MR image capturing following the first MR image capturing based on the phase distribution data.

Various Embodiments will be described hereinafter with reference to the accompanying drawings.

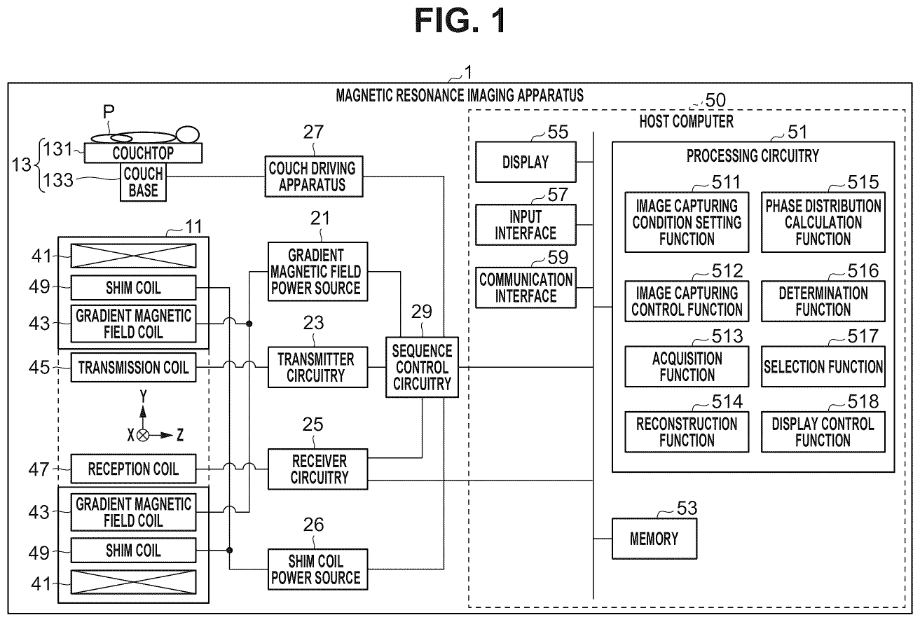

FIG. 1 is a diagram illustrating a configuration example of a magnetic resonance imaging apparatus 1 according to the present embodiment. As illustrated in FIG. 1, the magnetic resonance imaging apparatus 1 includes a gantry 11, a couch 13, a gradient magnetic field power source 21, transmitter circuitry 23, receiver circuitry 25, a shim coil power source 26, a couch driving apparatus 27, sequence control circuitry 29, and a host computer 50.

The gantry 11 includes a static magnetic field magnet 41, a gradient magnetic field coil 43, and a shim coil 49. The static magnetic field magnet 41, the gradient magnetic field coil 43, and the shim coil 49 are housed in a casing of the gantry 11. A bore having a hollow shape is formed in the casing of the gantry 11. A transmission coil 45 and a reception coil 47 are arranged in the bore of the gantry 11.

The static magnetic field magnet 41 has a hollow, substantially-cylindrical shape and generates a static magnetic field inside a substantially cylindrical portion. As the static magnetic field magnet 41, for example, a permanent magnet, a superconducting magnet, a resistive magnet, or the like is used. Here, a central axis of the static magnetic field magnet 41 is defined as a Z-axis, an axis orthogonal to the Z-axis in the vertical direction is defined as a Y-axis, and an axis orthogonal to the Z-axis in the horizontal direction is defined as an X-axis. The X-axis, the Y-axis, and the Z-axis form an orthogonal three-dimensional coordinate system.

The gradient magnetic field coil 43 is a coil unit attached to the inside of the static magnetic field magnet 41 and formed into a hollow, substantially-cylindrical shape. The gradient magnetic field coil 43 generates a gradient magnetic field upon receiving supply of a current from the gradient magnetic field power source 21. More specifically, the gradient magnetic field coil 43 includes three coils corresponding to the X-axis, the Y-axis, and the Z-axis that are orthogonal to each other. The three coils form gradient magnetic fields that vary in magnetic field intensity along the respective axes of the X-axis, the Y-axis, and the Z-axis. The gradient magnetic fields along the respective axes of the X-axis, the Y-axis, and the Z-axis are combined to form a slice-select gradient magnetic field Gs, a phase-encoding gradient magnetic field Gp, and a frequency-encoding gradient magnetic field Gr that are orthogonal to each other in a desired direction. The slice-select gradient magnetic field Gs is used to arbitrarily determine an imaging plane (slice). The phase-encoding gradient magnetic field Gp is used to vary the phase of a magnetic resonance (MR) signal (hereinafter, referred to as an MR signal) in accordance with a spatial location. The frequency-encoding gradient magnetic field Gr is used to vary the frequency of an MR signal in accordance with a spatial location. In the following description, a gradient direction of the slice-select gradient magnetic field Gs is assumed to be along the Z-axis, a gradient direction of the phase-encoding gradient magnetic field Gp is assumed to along the Y-axis, and a gradient direction of the frequency-encoding gradient magnetic field Gr is assumed to be along the X-axis.

The gradient magnetic field power source 21 supplies current to the gradient magnetic field coil 43 in accordance with a control signal from the sequence control circuitry 29. By supplying a current to the gradient magnetic field coil 43, the gradient magnetic field power source 21 generates the gradient magnetic fields along the respective axes of the X-axis, the Y-axis, and the Z-axis from the gradient magnetic field coil 43. The gradient magnetic fields are superimposed on a static magnetic field formed by the static magnetic field magnet 41 and are applied to a subject P.

The transmission coil 45 is arranged inside the gradient magnetic field coil 43, for example, and generates a high-frequency pulse (hereinafter, referred to as a radio frequency (RF) pulse) by receiving supply of a current from the transmitter circuitry 23.

The transmitter circuitry 23 supplies a current to the transmission coil 45 to apply an RF pulse for exciting a target proton such as a hydrogen nuclei that exists in the subject P to the subject P via the transmission coil 45. The RF pulse vibrates at a resonant frequency unique to the target proton, and excites the target proton. An MR signal is generated from the excited target proton and detected by the reception coil 47. The transmission coil 45 is a whole body coil (WB coil), for example. The whole body coil may be used as a transmission/reception coil.

Upon receiving an action of the RF pulse, the reception coil 47 receives an MR signal emitted from the target proton existing inside the subject P. The reception coil 47 includes a plurality of reception coil elements that can receive MR signals. The received MR signal is supplied to the receiver circuitry 25 via a cable or wirelessly. The reception coil 47 includes a plurality of reception channels mounted in parallel, which is not illustrated in FIG. 1. Each reception channel includes a reception coil element that receives an MR signal, an amplifier that amplifies the MR signal, and the like. The MR signal is output for each reception channel. The total number of reception channels and the total number of reception coil elements may be the same, or the total number of reception channels may be larger as compared with the total number of reception coil elements.

The receiver circuitry 25 receives an MR signal generated from an excited target proton, via the reception coil 47. The receiver circuitry 25 generates a digital MR signal by performing signal processing on the received MR signal. The digital MR signal is expressed in a k-space defined by a spatial frequency. Hereinafter, the digital MR signal will be referred to as k-space data. The k-space data is supplied to the host computer 50 via a cable or wirelessly.

The transmission coil 45 and the reception coil 47 described above are mere examples. A transmission/reception coil having a transmission function and a receiving function may be used in place of the transmission coil 45 and the reception coil 47. Further, the transmission coil 45, the reception coil 47, and the transmission/reception coil may be combined.

The shim coil 49 is a coil unit attached to the inside of the static magnetic field magnet 41. Upon receiving supply of a current from the shim coil power source 26, the shim coil 49 generates a correction magnetic field for correcting inhomogeneity of a static magnetic field. The inhomogeneity of the static magnetic field has a zeroth-order component, a first-order component, a second-order component, and a high-order components of third order and above. The shim coil 49 generates a correction magnetic field for correcting all or part of these components.

The shim coil power source 26 supplies a current to the shim coil 49 in accordance with a control signal from the sequence control circuitry 29. Specifically, upon receiving data of a magnetic field inhomogeneity correction value from the sequence control circuitry 29, the shim coil power source 26 supplies a current corresponding to each component of the correction magnetic field to the shim coil 49 in accordance with the magnetic field inhomogeneity correction value. The correction magnetic field is thereby generated from the shim coil 49. The magnetic field inhomogeneity correction value refers to a value of a current to be supplied to the shim coil 49 to homogenize a static magnetic field.

The couch 13 is installed adjacent to the gantry 11. The couch 13 includes a couchtop 131 and a couch base 133. The subject P is placed on the couchtop 131. The couch base 133 supports the couchtop 131 to be slidable along the X-axis, the Y-axis, and the Z-axis. The couch driving apparatus 27 is housed in the couch base 133. The couch driving apparatus 27 moves the couchtop 131 under control of the sequence control circuitry 29. The couch driving apparatus 27 may include a motor such as a servomotor or a stepping motor, for example.

The sequence control circuitry 29 includes, as hardware resources, a processor such as a central processing unit (CPU) or a micro processing unit (MPU), and a memory such as a read only memory (ROM) or a random access memory (RAM). The sequence control circuitry 29 synchronously controls the gradient magnetic field power source 21, the transmitter circuitry 23, and the receiver circuitry 25 based on an image capturing condition set by processing circuitry 51, performs MR image capturing of the subject P in accordance with the image capturing condition, and collects k-space data regarding the subject P. As MR image capturing, image capturing for morphological image collection, shimming image capturing for shimming map collection, magnetic resonance spectroscopy (MRS) image capturing, chemical exchange saturation transfer (CEST) image capturing, and the like are possible.

By the sequence control circuitry 29 executing various types of MR image capturing, an MR signal is generated from an image capturing region set in the subject P. The receiver circuitry 25 receives the MR signal via the reception coil 47, and collects k-space data by performing signal processing on the received MR signal.

As illustrated in FIG. 1, the host computer 50 is a computer including the processing circuitry 51, a memory 53, a display 55, an input interface 57, and a communication interface 59.

The processing circuitry 51 includes, as a hardware resource, a processor such as a CPU. The processing circuitry 51 functions as a center of the magnetic resonance imaging apparatus 1. For example, by execution of various programs, the processing circuitry 51 implements an image capturing condition setting function 511, an image capturing control function 512, an acquisition function 513, a reconstruction function 514, a phase distribution calculation function 515, a determination function 516, a selection function 517, and a display control function 518.

By the image capturing condition setting function 511, the processing circuitry 51 sets an image capturing condition related to MR image capturing. The image capturing condition includes an image capturing position, a magnetic field homogeneity correction value, the order (before/after) of image capturing with respect to administration of a contrast agent, a data collection trajectory, a pulse sequence, an echo time, a voxel size, a voxel position, a water suppression parameter, and/or the like. The image capturing position indicates a position of a slice or a volume. The magnetic field homogeneity correction value refers to a value of a current to be supplied to the shim coil 49 to homogenize a static magnetic field in an image capturing space. The magnetic field homogeneity correction value is calculated based on a shimming map. The order (before/after) of image capturing with respect to the administration of a contrast agent is information indicating whether the image capturing is performed before or after the administration of a contrast agent. The data collection trajectory is also referred to as a k-space trajectory, and includes Cartesian collection and non-Cartesian collection. Examples of the non-Cartesian collection include Echo Planner Imaging (EPI) collection, radial collection, spiral collection, three-dimensional radial collection, stack-of-stars collection, and the like. The pulse sequence includes a spin echo system, a Field Echo (FE) (Gradient Echo (GRE)) system, an EPI collection, and the like for MR image collection, and includes point resolved spectroscopy (PRESS), Mescher-Garwood point resolved spectroscopy (MEGA-PRESS), and the like for spectrum collection. The echo time refers to a time from an application of an excitation pulse to a re-convergence of transverse magnetization. The voxel size is the size of a voxel that is a space region for which a spectrum is collected. The voxel position is a set position of the voxel. The water suppression parameter refers to a frequency range of a water suppression pulse to be applied in MRS image capturing. The image capturing condition setting function 511 serves as an example of a setting unit.

In addition, the processing circuitry 51 can change the above-described image capturing condition by the image capturing condition setting function 511. The image capturing condition setting function 511 is an example of a change unit.

By the image capturing control function 512, the processing circuitry 51 controls the sequence control circuitry 29, performs various types of MR image capturing on the subject P, and collects k-space data via the receiver circuitry 25. The MR image capturing according to the present embodiment is mainly classified into shimming image capturing, first MR image capturing, second MR image capturing, and the like. The second MR image capturing is MR image capturing for which the necessity of change is to be determined by the determination function 516. The second MR image capturing follows the first MR image capturing. The second MR image capturing is image capturing for image collection (hereinafter, MR image capturing) or image capturing for spectrum collection (hereinafter, spectrum image capturing). The first MR image capturing is MR image capturing for collecting data to be used in determining the necessity of change of the second MR image capturing. As an example, the data is morphological image data. In short, the first MR image capturing is MR image capturing. The shimming image capturing is image capturing for collecting a shimming map. The first MR image capturing and the second MR image capturing can be applied to both contrast image capturing in which a subject to which a contrast agent is administered is an image capturing target and non-contrast image capturing in which a subject to which a contrast agent is not administered is an image capturing target. In addition, in a case where a value of an image capturing condition is changed by the image capturing condition setting function 511, the processing circuitry 51 performs the second MR image capturing on the subject P in accordance with the changed value. The image capturing control function 512 is an example of a collection unit.

By the acquisition function 513, the processing circuitry 51 acquires various types of information. For example, the processing circuitry 51 acquires k-space data from the receiver circuitry 25. In addition, the processing circuitry 51 may acquire medical image data collected by another modality, non-image data described in an electronic medical record, and/or contrast agent information. The acquisition function 513 is an example of an acquisition unit.

By the reconstruction function 514, the processing circuitry 51 reconstructs MR image data based on k-space data. As an example, the processing circuitry 51 generates image data representing the morphology of the subject P (hereinafter, referred to as magnetic resonance morphological image data) based on k-space data collected by the first MR image capturing. As another example, the processing circuitry 51 generates a shimming map based on k-space data collected by the shimming image capturing. The shimming map is an image indicating a spatial distribution of a phase difference that is a difference between two types of phase images with different echo times. The phase difference is proportional to a static magnetic field intensity or a resonant frequency. From another viewpoint, the shimming map can also be expressed as an image representing a spatial distribution of a resonant frequency difference from a central frequency. The reconstruction function 514 is an example of a generation unit.

By the phase distribution calculation function 515, the processing circuitry 51 calculates phase distribution data indicating a spatial distribution including phase information, based on at least magnetic resonance morphological image data. The phase distribution data represents the spatial distribution of physical quantities such as the phase of a magnetization vector present in an image capturing region, or magnetic susceptibility related to the phase. The phase distribution calculation function 515 is an example of a calculation unit.

By the determination function 516, the processing circuitry 51 determines the necessity of a change of the second MR image capturing following the first MR image capturing, based on the phase distribution data calculated by the phase distribution calculation function 515. In a case where a representative value of the phase distribution data is less than a reference value, the processing circuitry 51 determines that the second MR image capturing does not need to be changed. In the case where the representative value is less than the reference value, it means that inhomogeneity of a magnetic field is relatively small. On the other hand, in a case where the representative value is greater than the reference value, the processing circuitry 51 determines that the second MR image capturing needs to be changed. In the case where the representative value is greater than the reference value, it means that the inhomogeneity of a magnetic field is relatively large. The determination function 516 is an example of a determination unit.

By the selection function 517, the processing circuitry 51 selects a type and/or a recommended value of an image capturing condition that is recommended to be changed and that affects a T2 shortening effect, an echo time, and/or a magnetic field homogeneity, among image capturing conditions related to the second MR image capturing in a case where it is determined by the determination function 516 that the second MR image capturing needs to be changed. Hereinafter, an image capturing condition recommended to be changed will be referred to as a change recommended condition. The selection function 517 is an example of a selection unit.

By the display control function 518, the processing circuitry 51 displays various types of information on the display 55. As an example, the processing circuitry 51 displays a type and/or a recommended value of the change recommended condition selected by the selection function 517. As another example, the processing circuitry 51 displays a determination result by the determination function 516.

The memory 53 is a storage device such as a hard disk drive (HDD), a solid state drive (SSD), or an integrated circuit storage device, that stores various types of information. Further, the memory 53 may be a drive device or the like that reads and writes various types of information from and into a portable storage medium such as a compact disc (CD)-ROM drive, a digital versatile disc (DVD) drive, or a flash memory.

The display 55 displays various types of information by the display control function 518. As the display 55, for example, a cathode-ray tube (CRT) display, a liquid crystal display, an organic electroluminescence (EL) display, a light-emitting diode (LED) display, a plasma display, or any other display known in the technical field can be used as appropriate.

The input interface 57 includes an input device for receiving various commands from a user. As the input device, a keyboard, a mouse, various switches, a touch screen, a touch pad, and the like can be used. The input device is not limited to an input device including a physical operational component such as a mouse or a keyboard. For example, electric signal processing circuitry that receives an electric signal corresponding to an input operation from an external input device provided separately from the magnetic resonance imaging apparatus 1 and outputs the received electric signal to various kinds of circuitry is also an example of the input interface 57. In addition, the input interface 57 may be a speech recognition device that converts a speech signal collected by a microphone into an instruction signal.

The communication interface 59 is an interface that connects the magnetic resonance imaging apparatus 1 with a work station, a picture archiving and communication system (PACS), a hospital information system (HIS), a radiology information system (RIS), and the like via a local area network (LAN) or the like. A network interface (IF) transmits and receives various types of information to and from the work station, the PACS, the HIS, and the RIS that are connection destinations.

Next, phase distribution data calculation processing to be executed by the phase distribution calculation function 515 will be described.

By the phase distribution calculation function 515, the processing circuitry 51 generates phase distribution data by applying the magnetic resonance morphological image data reconstructed by the reconstruction function 514 to a trained model (hereinafter, phase distribution estimation model). The phase distribution estimation model is a machine learning model trained based on a training sample including magnetic resonance morphological image data that is input data and phase distribution data that is output data. The phase distribution estimation model is generated by the processing circuitry 51, for example.

The phase distribution data is a magnetic field homogeneity map, a susceptibility weighted imaging (SWI) image, or a quantitative susceptibility mapping (QSM) image. Similar to the shimming map, the magnetic field homogeneity map is an image representing a spatial distribution of a phase difference that is a difference between two types of phase images having different echo times. The SWI image is an image representing a spatial distribution of a difference in magnetic susceptibility. The QSM image is an image representing a quantitative spatial distribution of magnetic susceptibility.

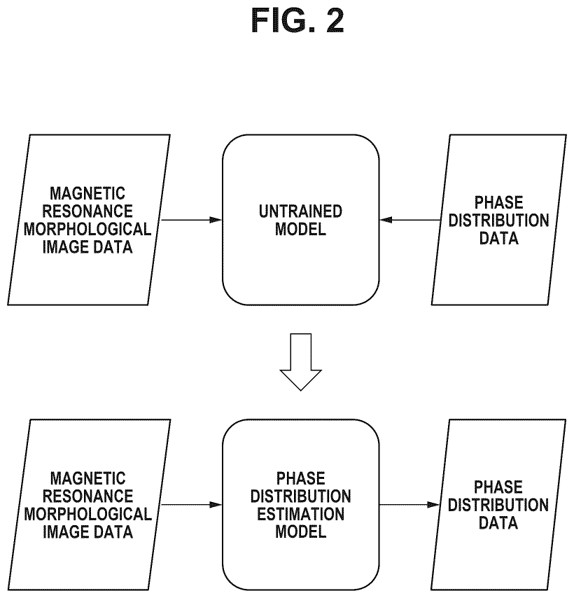

FIG. 2 is a diagram illustrating a generation process of a phase distribution estimation model according to the present embodiment. As illustrated in FIG. 2, the processing circuitry 51 trains an untrained model based on a plurality of training samples including magnetic resonance morphological image data that is input data and phase distribution data that is output data. The phase distribution data is used as ground truth data. Hereinafter, phase distribution data included in a training sample is referred to as ground truth phase distribution data. The magnetic resonance morphological image data and the phase distribution data are data regarding the same subject, and may be data collected in the same examination, or may be data collected in different examinations. In addition, the subjects may be the same or different over a plurality of training samples. The magnetic resonance morphological image data and the phase distribution data may be artificially-generated data instead of being data collected by MR image capturing.

The untrained model refers to a machine learning model before network parameters such as a weight parameter and a bias are optimized. Specifically, a neural network is used as the machine learning model. The machine learning model includes a combination of an input layer, an output layer, a fully connected layer, a convolution layer, a pooling layer, a normalization layer, an attention mechanism, and any other network layer. A network configuration of the machine learning model is not particularly limited, and any network configuration may be employed as long as image data can be input and output.

The processing circuitry 51 updates parameters of an untrained model using any optimization algorithm by supervised learning that is based on a plurality of training samples. As the optimization algorithm, stochastic gradient descent, Adam, and other algorithms can be used. For example, the processing circuitry 51 generates predicted phase distribution data by performing forward propagation processing on magnetic resonance morphological image data in accordance with the network configuration of the untrained model. Next, the processing circuitry 51 calculates a loss value, which is an error between the predicted phase distribution data and the ground truth phase distribution data, based on a loss function. The processing circuitry 51 updates parameters of the untrained model so that the loss value becomes smaller. The untrained model thereby learns a correlation between the magnetic resonance morphological image data and the phase distribution data.

The processing circuitry 51 repeats the generation of the predicted phase distribution data, the calculation of the loss value, and the update of parameters until an end condition is satisfied. The end condition may be set to a condition that the number of repetitions has reached a predetermined number, a condition that the loss value converges to a value smaller than a predetermined value, a condition that the accuracy of predicted phase distribution data has reached a predetermined value, or the like. A set of parameters when the end condition is satisfied is stored in the memory 53 as optimum parameters. A machine learning model to which the optimum parameters are assigned is used as a phase distribution estimation model.

In an operational phase, by applying magnetic resonance morphological image data related to a subject to a phase distribution estimation model, the processing circuitry 51 generates phase distribution data related to the subject. By using the phase distribution estimation model, it becomes possible to generate phase distribution data corresponding to the magnetic resonance morphological image data.

For example, in a case where a shimming map is used as the ground truth phase distribution data, phase distribution data output from the phase distribution estimation model in the operational phase is a magnetic field homogeneity map. Generally, the shimming map is generated at a spatial resolution lower than that of the magnetic resonance morphological image data. In this manner, in a case where the spatial resolutions of the magnetic resonance morphological image data and the shimming map differ, the spatial resolutions of both image data may be made uniform. Specifically, the processing circuitry 51 may set a shimming map that has been upsampled to match the spatial resolution of the magnetic resonance morphological image data as a ground truth shimming map for a training sample. As another example, a network layer that upsamples the spatial resolution of the shimming map to match the spatial resolution of the magnetic resonance morphological image data may be added to the phase distribution estimation model.

Various patterns of input-output may be possible for the phase distribution estimation model. The magnetic resonance morphological image data that is input data may include one or more images of a complex image, a magnitude image, and a phase image. The phase distribution data that is output data may include a magnetic field homogeneity map, an SWI image, or a QSM image.

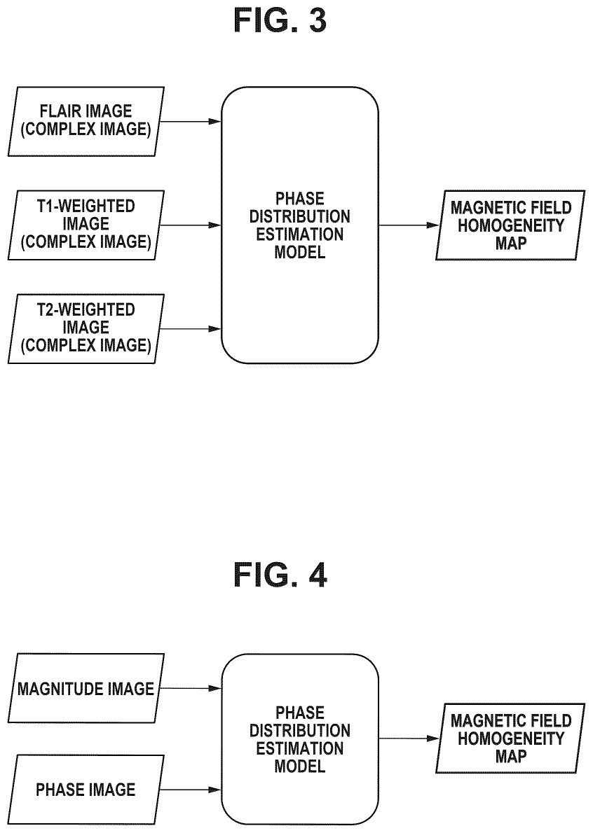

FIG. 3 is a diagram illustrating an example of inputs and an output of a phase distribution estimation model. To the phase distribution estimation model illustrated in FIG. 3, a fluid-attenuated inversion recovery (FLAIR) image, a T1-weighted image, and a T2-weighted image that are related to the same image capturing region of the same subject are input, and the phase distribution estimation model outputs a magnetic field homogeneity map related to the image capturing region of the subject. The FLAIR image, the T1-weighted image, and the T2-weighted image are examples of a complex image. The present embodiment is not limited to using all of the FLAIR image, the T1-weighted image, and the T2-weighted image as the inputs, and two or one of the FLAIR image, the T1-weighted image, and the T2-weighted image may be used as inputs. In a case where a magnetic field homogeneity map is the output data, a shimming map is used as the phase distribution data of a training sample.

FIG. 4 is a diagram illustrating another example of inputs and an output of the phase distribution estimation model. To the phase distribution estimation model illustrated in FIG. 4, a magnitude image and a phase image that are related to the same image capturing region of the same subject are input, and the phase distribution estimation model outputs a magnetic field homogeneity map related to the image capturing region of the subject. The magnitude image can be generated as a real part image of an arbitrary complex image, and the phase image can be generated as an imaginary part image of the complex image. The present embodiment is not limited to using all of the magnitude image and the phase image as the inputs, and either the magnitude image or the phase image may be used as the input. In a case where a magnetic field homogeneity map is the output data, a shimming map is used as the phase distribution data of a training sample.

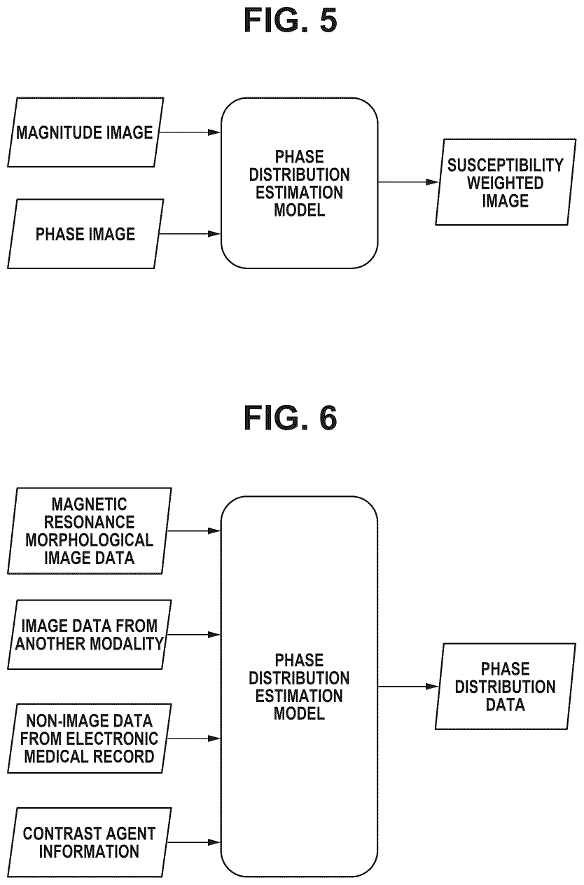

FIG. 5 is a diagram illustrating another example of inputs and an output of the phase distribution estimation model. To the phase distribution estimation model illustrated in FIG. 5, a magnitude image and a phase image that are related to the same image capturing region of the same subject are input, and the phase distribution estimation model outputs a susceptibility weighted image related to the image capturing region of the subject. The magnitude image can be generated as a real part image of an arbitrary complex image, and the phase image can be generated as an imaginary part image of the complex image. The present embodiment is not limited to using all of the magnitude image and the phase image as the inputs, and only the magnitude image may be used as the input. In a case where a susceptibility weighted image is the output data, a susceptibility weighted image is used as the phase distribution data of a training sample.

In a case where a magnitude image and a phase image that are related to the same image capturing region of the same subject are used as input data, a QSM image related to the image capturing region of the subject may be used as the output data. In this case, the QSM image is used as the phase distribution data of a training sample.

Input data of the phase distribution estimation model is not limited to magnetic resonance morphological image data. As the input data, aside from the magnetic resonance morphological image data, medical image data collected by another modality (image data from another modality), non-image data described in an electronic medical record (non-image data from an electronic medical record), and/or contrast agent information may be used. The phase distribution estimation model is a machine learning model trained based on a training sample including morphological image data, medical image data collected by another modality, non-image data described in an electronic medical record, and/or contrast agent information, which serve(s) as the input data, and phase distribution data serving as the output data.

The image data from another modality refers to image data collected by an X-ray computed tomography apparatus, an X-ray diagnostic apparatus, an ultrasound imaging apparatus, or a nuclear medicine diagnostic apparatus. It is desirable that the magnetic resonance image data and the image data from another modality are image data related to the same image capturing region of the same subject. The non-image data from an electronic medical record is data of character strings related to a disease name, blood information, a gene, and the like that are described in an electronic medical record. The contrast agent information refers to information indicating whether a contrast agent has been administered to a subject at the time of image capturing of magnetic resonance morphological image data or image data from another modality, and if administered, is information regarding the type, an administration speed, and the like of the contrast agent.

FIG. 6 is a diagram illustrating another example of inputs and an output of the phase distribution estimation model. To the phase distribution estimation model illustrated in FIG. 6, magnetic resonance morphological image data, medical image data collected by another modality (image data from another modality), non-image data described in an electronic medical record (non-image data from an electronic medical record), and contrast agent information that are related to the same subject are input, and the phase distribution estimation model outputs phase distribution data related to the subject. The magnetic resonance morphological image data, the image data from another modality, and the phase distribution data are image data related to the same image capturing region of the subject. As the inputs to the phase distribution estimation model, aside from the magnetic resonance morphological image data, the present embodiment is not limited to inputting all of the image data from another modality, the non-image data from an electronic medical record, and the contrast agent information, and a part of the image data from another modality, the non-image data from an electronic medical record, and the contrast agent information may be input.

Next, an operation example of an MR examination executed by the magnetic resonance imaging apparatus 1 will be described.

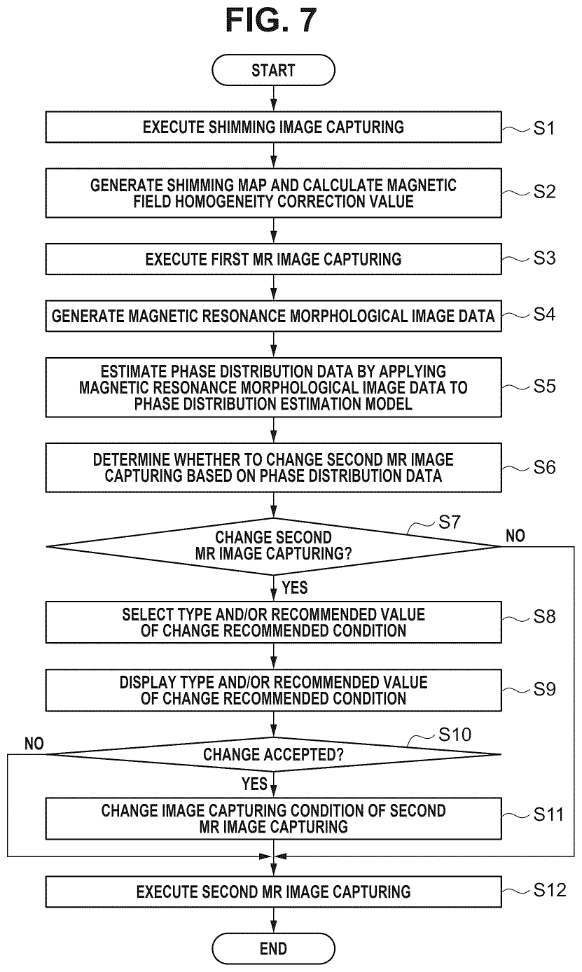

FIG. 7 is a diagram illustrating a typical flow of an MR examination executed by the magnetic resonance imaging apparatus 1 according to the present embodiment. It is assumed that, before a start of the MR examination, a phase distribution estimation model is already generated and stored in the memory 53 or the like. The following embodiment can be applied to any of the phase distribution estimation models described above. However, to provide a concrete description, the phase distribution estimation model illustrated in FIG. 2 is used as an example.

As illustrated in FIG. 7, first, in step S1, by the image capturing control function 512, the processing circuitry 51 controls the sequence control circuitry 29 and executes shimming image capturing of the subject P. Through the shimming image capturing, k-space data is collected by the receiver circuitry 25. By the acquisition function 513, the processing circuitry 51 acquires the collected k-space data. After step S1 is performed, in step S2, by the reconstruction function 514, the processing circuitry 51 generates a shimming map based on the k-space data collected in step S1. As an example, in step S1, the sequence control circuitry 29 executes a pulse sequence of a gradient echo at low resolution twice, and the receiver circuitry 25 collects two sets of k-space data. In step S2, the processing circuitry 51 generates the shimming map indicating a spatial distribution of static magnetic field deviations based on the two sets of k-space data. The static magnetic field deviation can be obtained by, for example, phase difference/time difference [rad/s]. By the image capturing condition setting function 511, the processing circuitry 51 calculates a magnetic field homogeneity correction value for spatially uniformizing the static magnetic field deviation based on the shimming map.

After step S2 is performed, in step S3, by the image capturing control function 512, the processing circuitry 51 controls the sequence control circuitry 29, and executes first MR image capturing of the subject P in accordance with the magnetic field homogeneity correction value. Through the first MR image capturing, k-space data is collected by the receiver circuitry 25. By the acquisition function 513, the processing circuitry 51 acquires the collected k-space data. After step S3 is performed, in step S4, by the reconstruction function 514, the processing circuitry 51 generates magnetic resonance morphological image data based on the k-space data collected in step S3.

The shimming image capturing and the first MR image capturing according to the present embodiment may be either contrast image capturing or non-contrast image capturing as long as the same image capturing is performed in both the shimming image capturing and the first MR image capturing. The first MR image capturing and the second MR image capturing may also be either the contrast image capturing or the non-contrast image capturing.

After step S4 is performed, in step S5, by the phase distribution calculation function 515, the processing circuitry 51 estimates phase distribution data by applying the magnetic resonance morphological image data generated in step S4 to the phase distribution estimation model. In step S5, the processing circuitry 51 reads a phase distribution estimation model from the memory 53, inputs the magnetic resonance morphological image data to the read phase distribution estimation model, performs forward propagation processing corresponding to the network configuration of the phase distribution estimation model, generates phase distribution data, and outputs the phase distribution data from the phase distribution estimation model. A spatial range of the phase distribution data can be arbitrarily set. For example, in the case of MR image capturing, phase distribution data related to an entire image capturing range may be generated, or phase distribution data limited to an image capturing target region may be generated. In the case of MRS image capturing, phase distribution data limited to the inside of volume of interest (VOI) may be generated, or phase distribution data related to the inside of the VOI and a surrounding region thereof may be generated. The surrounding region may be a region within a range of a predetermined number of voxels from the VOI, or may be a region arbitrarily designated by the user. In addition, the phase distribution data can be arbitrarily selected from among a magnetic field homogeneity map, a susceptibility weighted image, and a QSM image.

After step S5 is performed, in step S6, by the determination function 516, the processing circuitry 51 determines the necessity of a change of the second MR image capturing based on the phase distribution data calculated in step S5. Specifically, first, the processing circuitry 51 calculates a representative value of the phase distribution data. A method for calculating the representative value varies depending on whether the second MR image capturing is the contrast image capturing or the non-contrast image capturing. In a case where the second MR image capturing is the contrast image capturing, the processing circuitry 51 calculates the representative value based on a data value of the phase distribution data.

Specifically, in a case where the data value of the phase distribution data is not a quantitative value, the processing circuitry 51 sets a relative value (specifically, a difference value) between a data value of a pixel inside an image capturing target region and a data value of a pixel outside the image capturing target region as a representative value. “The case where the data value of the phase distribution data is not a quantitative value” specifically corresponds to a case where a magnetic field homogeneity map or a susceptibility weighted image is used as the phase distribution data. In a case where the data value of the phase distribution data is a quantitative value, the processing circuitry 51 sets a data value of a pixel inside the image capturing target region as the representative value. “The case where the data value of the phase distribution data is a quantitative value” specifically corresponds to a case where a QSM image is used as the phase distribution data.

On the other hand, in a case where the second MR image capturing is the non-contrast image capturing, the processing circuitry 51 calculates the representative value based on a difference value between a data value of the phase distribution data and a data value of a shimming map collected by shimming image capturing executed before or after the first MR image capturing. For example, the processing circuitry 51 calculates the representative value based on a difference value between a data value of the phase distribution data generated in step S5 and a data value of the shimming map generated in step S2.

The “data value of the phase distribution data” refers to a statistical value of all pixels or partial pixels inside or outside an image capturing target region. As the statistical value, an average value, an intermediate value, a minimum value, a maximum value, or another statistical value of a plurality of pixels may be used. As another example, a pixel value of any one pixel of pixels inside or outside the image capturing target region may be used as the representative value.

When the representative value of the phase distribution data is calculated, the processing circuitry 51 compares the representative value of the phase distribution data with the reference value. The reference value may be set to any value. In a case where the representative value of the phase distribution data is less than the reference value, the processing circuitry 51 determines that the second MR image capturing does not need to be changed, and in a case where the representative value is greater than the reference value, the reference value, the processing circuitry 51 determines that the second MR image capturing needs to be changed.

In step S7, in a case where the processing circuitry 51 determines that the second MR image capturing is to be changed (YES in step S7), the processing proceeds to step S8. In step S8, by the selection function 517, the processing circuitry 51 selects the type and/or a recommended value of a change recommended condition. In step S8, the processing circuitry 51 selects the type and/or a recommended value of a change recommended condition. The processing circuitry 51 selects, as the change recommended condition, an image capturing position, a magnetic field homogeneity correction value, the order (before/after) of image capturing with respect to administration of a contrast agent, or an image capturing parameter. An image capturing parameter may be selected from among a data collection trajectory, a pulse sequence, an echo time, a voxel size, a voxel position and/or a water suppression parameter.

The type of a change recommended condition may vary depending on whether the second MR image capturing is the contrast image capturing or the non-contrast image capturing. In a case where the second MR image capturing is the contrast image capturing, the type of the change recommended condition is desirably selected from among the order (before/after) of image capturing with respect to administration of a contrast agent, a data collection trajectory, a pulse sequence, an echo time, a voxel size, a voxel position, and a water suppression parameter. In a case where the second MR image capturing is the MR image capturing, the type of the image capturing parameter is desirably selected from among the data collection trajectory, the pulse sequence, and the echo time. In a case where the second MR image capturing is the MRS image capturing, the type of the image capturing parameter is desirably selected from among the pulse sequence, the voxel size, the voxel position, the echo time, and the water suppression parameter. In a case where the second MR image capturing is the CEST image capturing, the type of the image capturing parameter is desirably selected from among the pulse sequence, the voxel size, the voxel position, the echo time, and the water suppression parameter. In a case where the second MR image capturing is the non-contrast image capturing, the type of the change recommended condition is desirably selected from among the image capturing position and the magnetic field homogeneity correction value.

The recommended value of the change recommended condition may be manually determined by the user via the input interface 57, or may be automatically determined in accordance with a condition empirically defined from viewpoints of a T2 shortening effect, an echo time, and/or a magnetic field homogeneity. In a case where there is no need to present a recommended value, the recommended value does not need to be determined.

As an example, the processing circuitry 51 determines whether each value of the image capturing parameter of the second MR image capturing satisfies a determination condition related to a T2 shortening effect, an echo time, and/or a magnetic field homogeneity (hereinafter, change determination condition), and selects an image capturing parameter including a value not satisfying the change determination condition as the change recommended condition. The change determination condition is registered in a look-up table (LUT) in which the type of the image capturing parameter is associated with the recommended value that the image capturing parameter is to have from the viewpoint of the T2 shortening effect, the echo time, and/or the magnetic field homogeneity. The recommended value may be registered as one or a plurality of discrete values, or may be registered as a range from an upper limit value to a lower limit value.

For each image capturing parameter of the second MR image capturing, the processing circuitry 51 compares a default value of the image capturing parameter with a recommended value registered in the LUT. In a case where the default value matches the recommended value, the processing circuitry 51 does not select the image capturing parameter as the change recommended condition. On the other hand, in a case where the default value does not match the recommended value, the processing circuitry 51 selects the image capturing parameter as the change recommended condition. In this case, the processing circuitry 51 outputs the type and the recommended value of the change recommended condition.

Hereinafter, specific examples of the change determination conditions to be used in the case where the second MR image capturing is the MR image capturing, in the case where the second MR image capturing is the MRS image capturing, and in the case where the second MR image capturing is the CEST image capturing will be separately described.

### MR Image Capturing

In a case where the type of the image capturing parameter is a data collection trajectory, because non-Cartesian collection such as EPI collection or spiral collection is sensitive to a magnetic field, Cartesian collection not sensitive to a magnetic field is set as a recommended value. In a case where the type of the image capturing parameter is a pulse sequence, because an FE (gradient echo) sequence is sensitive to a magnetic field, an SE (spin echo) sequence not sensitive to a magnetic field is set as the recommended value. In a case where the type of the image capturing parameter is an echo time, because the influence of a T2 shortening effect is smaller as the echo time is shorter, a relatively short value determined to have a small influence of the T2 shortening effect is set as the recommended value.

### MRS Image Capturing

In a case where the type of the image capturing parameter is a pulse sequence, because a MEGA-PRESS sequence is sensitive to a magnetic field, a PRESS sequence without a MEGA pulse is set as the recommended value. In a case where the type of the image capturing parameter is a voxel size, because the influence of a magnetic field homogeneity is smaller as the voxel size is smaller, a relatively small value determined to have a small magnetic field inhomogeneity is set as the recommended value. In a case where the type of the image capturing parameter is a voxel position, because a magnetic field homogeneity varies in accordance with the position, a position determined to have a small magnetic field inhomogeneity is set as the recommended value. In a case where the type of the image capturing parameter is an echo time, because the influence of a T2 shortening effect is smaller as the echo time is shorter, a relatively short value determined to have a small influence of a T2 shortening effect is set as the recommended value. In a case where the type of the image capturing parameter is a water suppression parameter, because it is desirable to expand the range of application frequency of the water suppression pulse in a case where the magnetic field homogeneity deteriorates, a range in which accuracy can be relatively secured even in a case where the magnetic field homogeneity deteriorates is set as the recommended value.

### CEST Image Capturing

In a case where the type of the image capturing parameter is a pulse sequence, because the FE (gradient echo) sequence is sensitive to a magnetic field, the SE (spin echo) sequence not sensitive to a magnetic field is set as the recommended value. In a case where the type of the image capturing parameter is a voxel size, because the influence of a magnetic field homogeneity is smaller as the voxel size is smaller, a relatively small value determined to have a small magnetic field inhomogeneity is set as the recommended value. In a case where the type of the image capturing parameter is a voxel position, because a magnetic field homogeneity varies in accordance with the position, a position determined to have a small magnetic field inhomogeneity is set as the recommended value. In a case where the type of the image capturing parameter is an echo time, because the influence of a T2 shortening effect is smaller as the echo time is shorter, a relatively short value determined to have a small influence of the T2 shortening effect is set as the recommended value. In a case where the type of the image capturing parameter is a water suppression parameter, because it is desirable to expand the range of application frequency of the water suppression pulse in a case where the magnetic field homogeneity deteriorates, a range in which accuracy can be relatively secured even in a case where the magnetic field homogeneity deteriorates is set as the recommended value.

After step S8 is performed, in step S9, by the display control function 518, the processing circuitry 51 displays the type and/or the recommended value of the change recommended condition selected in step S8, on the display 55. The layout of the type and/or the recommended value of the change recommended condition can be freely set. The user checks the displayed type and/or recommended value of the change recommended condition, and determines whether to accept or reject the change of the change recommended condition. The type and/or the recommended value of the change recommended condition is an example of support information related to the second MR image capturing.

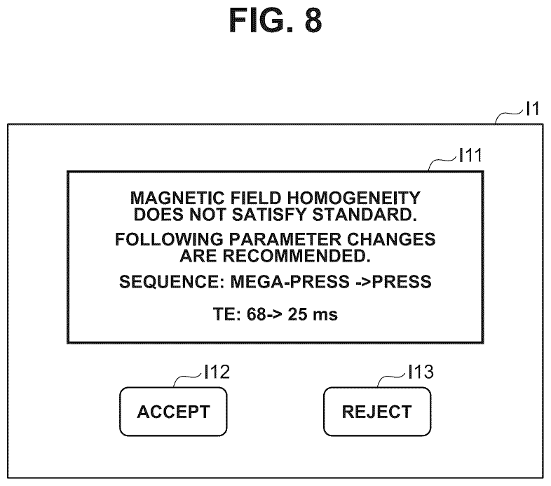

FIG. 8 is a diagram illustrating an example of a display screen I1 of the change recommended condition. As illustrated in FIG. 8, the display screen I1 includes a display field I11, an accept button I12, and a reject button I13. The display field I11 is a display region in which the necessity of a change of the second MR image capturing, and the type and/or the recommended value of the change recommended condition are displayed. For example, a determination result of the necessity of a change of the second MR image capturing is displayed in the display field I11, such as “The magnetic field homogeneity does not satisfy the standard”. The user can thereby recognize that the magnetic field homogeneity of the second MR image capturing is not good under the current image capturing condition. In addition, a message indicating that the type of the change recommended condition is a pulse sequence, and the recommended value of the change recommended condition is PRESS is displayed in the display field I11, such as “Sequence: MEGA-PRESS->PRESS”. The user can thereby recognize the type and/or the recommended value of the change recommended condition without finding them by himself or herself. In addition, an echo time at the recommended value may be displayed in the display field I11, such as “TE: 68->25 ms”. The user can thereby recognize a change in the echo time, which is one of important indices of the magnetic field homogeneity, that is caused by a change from a set value to the recommended value.

The accept button I12 is a graphical user interface (GUI) button for outputting a signal indicating that the change of the image capturing condition is accepted. In a case where the accept button I12 is pressed, the processing circuitry 51 determines that the change is accepted. The reject button I13 is a GUI button for outputting a signal indicating that the change of the image capturing condition is rejected. In a case where the reject button I13 is pressed, the processing circuitry 51 determines that the change is not accepted.

In a case where the change has been accepted (YES in step S10), the processing proceeds to step S11. In step S11, by the image capturing condition setting function 511, the processing circuitry 51 changes the image capturing condition of the second MR image capturing. In a case where the recommended value is selected in step S8, in step S11, the processing circuitry 51 changes the value of the image capturing condition to the recommended value. In a case where the change recommended condition and the magnetic field homogeneity correction value are related to the image capturing position, the processing circuitry 51 changes a slice position to an arbitrary position in accordance with an instruction issued by the user via the input interface 57. Then, by the image capturing control function 512, the processing circuitry 51 executes shimming image capturing at the changed slice position, and recalculates the magnetic field homogeneity correction value based on the collected k-space data. Until the user determines that the image capturing position and quality of the magnetic field homogeneity correction value are appropriate, the change of the slice position, the shimming image capturing, and the recalculation of the magnetic field homogeneity correction value are repeated.

In a case where step S11 is performed, in a case where the change is not accepted (NO in step S10), or in a case where it is determined that the second MR image capturing is not to be changed (NO in step S7), the processing proceeds to step S12. In step S12, by the image capturing control function 512, the processing circuitry 51 executes the second MR image capturing. In the case where the change is not accepted (NO in step S10), and in the case where it is determined that the second MR image capturing is not to be changed (NO in step S7), the second MR image capturing is performed under an unchanged image capturing condition. In the case where step S11 is performed, the second MR image capturing is performed under the changed change recommended condition. The second MR image capturing may be any of MR image capturing, MRS image capturing, or CEST image capturing.

Accordingly, the MR examination according to the present embodiment is completed.

As described above, the magnetic resonance imaging apparatus 1 according to the present embodiment includes the processing circuitry 51. The processing circuitry 51 collects the k-space data by performing the first MR image capturing of the subject P. The processing circuitry 51 generates the magnetic resonance morphological image data representing a morphology of the subject P based on the collected k-space data. The processing circuitry 51 calculates the phase distribution data representing the spatial distribution including the phase information based on at least the magnetic resonance morphological image data. The processing circuitry 51 determines the necessity of a change of the second MR image capturing following the first MR image capturing based on the phase distribution data.

According to the above-described configuration, the magnetic resonance imaging apparatus 1 calculates the phase distribution data based on the magnetic resonance morphological image data collected in the first MR imaging (first MR image capturing), and determines the necessity of a change of the second MR imaging (second MR image capturing) based on the phase distribution data. In this manner, the magnetic resonance imaging apparatus 1 can determine necessity of a change of third MR image capturing in consideration of phase distribution data affecting quality of data collected in MR image capturing, and accordingly can improve quality of data to be collected by the MR image capturing.

Next, several examples of the MR examination according to the present embodiment will be described.

### First Example

In a first example, the non-contrast image capturing is executed in the first MR image capturing and the second MR image capturing. The image capturing region is assumed to be a region including a relatively large number of boundaries between air and the image capturing region in the magnetic resonance morphological image data. For example, a breast, an abdomen, and the like include the relatively larger number of boundaries compared to a head where an image capturing target is a brain parenchyma. In this manner, in the case where a large number of boundaries are included, static magnetic field deviation is more likely to occur. Thus, an optimum value of the magnetic field homogeneity correction value with a good homogeneity of a static magnetic field is obtained by repeating the shimming image capturing while varying the image capturing position.

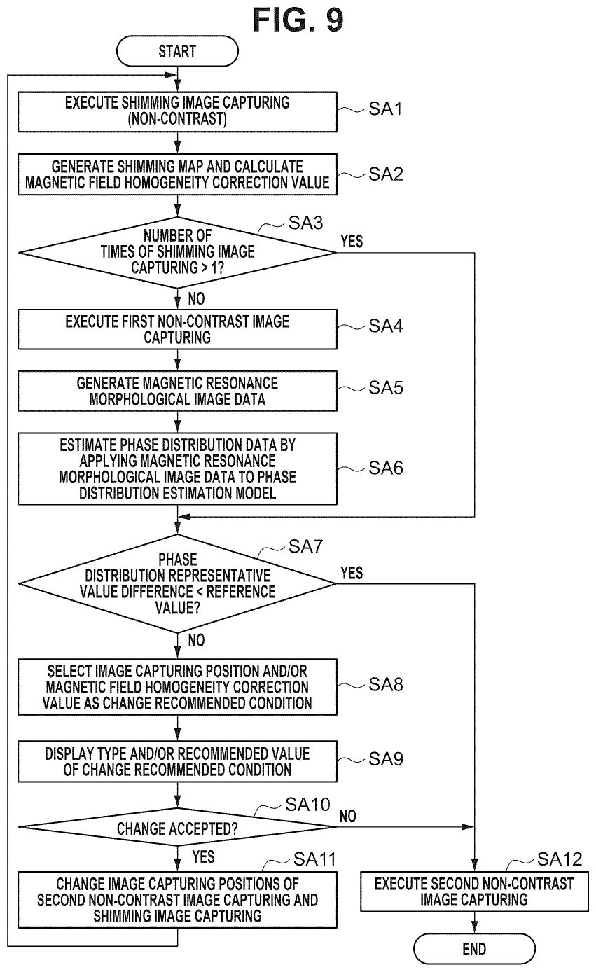

FIG. 9 is a diagram illustrating a typical flow of an MR examination executed by the magnetic resonance imaging apparatus 1 according to the first example. As illustrated in FIG. 9, in step SA1, first, by the image capturing control function 512, the processing circuitry 51 controls the sequence control circuitry 29 and executes shimming image capturing of the subject P. The shimming image capturing is performed in a non-contrast manner. After step SA1 is performed, in step SA2, by the reconstruction function 514, the processing circuitry 51 generates a shimming map based on k-space data collected in step SA1, and calculates a magnetic field homogeneity correction value based on the generated shimming map.

After step SA2 is performed, in step SA3, the processing circuitry 51 determines whether the number of times the shimming image capturing has been executed in the MR examination is larger than one. In initial step SA3 of the MR examination, because the shimming image capturing has been performed only once, it is determined that the number of times the shimming image capturing has been executed is not larger than one (NO in step SA3). In this case, the processing proceeds to step SA4. In step SA4, by the image capturing control function 512, the processing circuitry 51 controls the sequence control circuitry 29, and executes first non-contrast image capturing of the subject P. The non-contrast image capturing is assumed to be MR image capturing of the subject P to which a contrast agent has not been administered. The first non-contrast image capturing is an example of the first MR image capturing. Through the first non-contrast image capturing, k-space data is collected by the receiver circuitry 25. By the acquisition function 513, the processing circuitry 51 acquires the collected k-space data. After step SA4 is performed, in step SA5, by the reconstruction function 514, the processing circuitry 51 generates magnetic resonance morphological image data based on the k-space data collected in step SA4.

After step SA5 is performed, in step SA6, by the phase distribution calculation function 515, the processing circuitry 51 estimates phase distribution data by applying the magnetic resonance morphological image data generated in step SA5 to a phase distribution estimation model. In a case where step SA6 is performed, or in a case where it is determined in step SA3 that the number of times the shimming image capturing is executed is larger than one (YES in step SA3), the processing proceeds to step SA7. In step SA7, by the determination function 516, the processing circuitry 51 determines whether a representative value of the phase distribution data calculated in step SA6 is smaller than a reference value. As the representative value of the phase distribution data according to the first example, a difference value between the shimming map and the phase distribution data is used. As described above, because homogeneity of a static magnetic field is good in a state where a representative value of the phase distribution data is smaller than the reference value, the state means that an image capturing condition of second non-contrast image capturing is not to be changed, and because the homogeneity of a static magnetic field is not good in a state where the representative value of the phase distribution data is not smaller than a reference value, the state means that the image capturing condition of the second non-contrast image capturing is to be changed.

In a case where it is determined in step SA7 that the representative value of the phase distribution data is not smaller than the reference value (NO in step SA7), the processing proceeds to step SA8. In step SA8, by the selection function 517, the processing circuitry 51 selects an image capturing position and/or a magnetic field homogeneity correction value as the change recommended condition. After step SA8 is performed, in step SA9, by the display control function 518, the processing circuitry 51 displays the type and/or the recommended value of the change recommended condition selected in step SA8 on the display 55. The user checks the displayed type and/or recommended value of the change recommended condition, and determines whether to accept or reject the change of the change recommended condition.

In a case where the change of the change recommended condition is accepted (YES in step SA10), the processing proceeds to step SA11. In step SA11, by the image capturing condition setting function 511, the processing circuitry 51 changes image capturing positions of the second non-contrast image capturing and the shimming image capturing. Then, the processing circuitry 51 returns to step SA1 again, and in step SA1, the processing circuitry 51 executes second shimming image capturing at the changed image capturing position, and in step SA2, updates the shimming map and the magnetic field homogeneity correction value. A second shimming map and a magnetic field homogeneity correction value are stored in the memory 53. The first shimming map and the magnetic field homogeneity correction value may be deleted from the memory 53.

In second step SA3, since the number of times the shimming image capturing is executed is two, it is determined that the number of times the shimming image capturing is executed is larger than one (YES in step SA3), and the processing proceeds to step SA7. In step SA7, by the determination function 516, the processing circuitry 51 determines whether a representative value of the phase distribution data is smaller than the reference value. In second step SA7, a difference value between the phase distribution data based on the first non-contrast image capturing and a shimming map based on second shimming image capturing is used as the representative value. In this manner, until it is determined in step SA7 that the representative value of the shimming map is smaller than the reference value, steps SA1 to SA11 are repeated while varying the image capturing positions. Also in a case where the change of the change recommended condition is rejected in step SA10 (NO in step SA10), it is possible to exit from the repetition of step SA1 to SA11.

Then, in a case where it is determined in step SA7 that the representative value of the phase distribution data is smaller than the reference value (YES in step SA7) or in a case where it is determined in step SA10 that the change of the change recommended condition is rejected (NO in step SA10), the processing proceeds to step SA12. In step SA12, by the image capturing control function 512, the processing circuitry 51 controls the sequence control circuitry 29 based on the latest magnetic field homogeneity correction value, and executes the second non-contrast image capturing. The second non-contrast image capturing is an example of the second MR image capturing.

Accordingly, the MR examination according to the first example is completed.

As described above, according to the first example, in a case where the non-contrast image capturing is executed in both the first MR image capturing and the second MR image capturing, when an image capturing region requiring the shimming image capturing to be repeated while varying the image capturing position is a target, it is possible to determine the necessity of repetition of the shimming image capturing based on the phase distribution data. Accordingly, since the shimming image capturing is repeated only in a case where the repetition is required, throughput of the MR examination improves. In addition, because the shimming image capturing is appropriately repeated in a case where a magnetic field homogeneity is poor, it is possible to ensure quality of data to be collected in the second MR image capturing.

### Second Example

In a second example, the first MR image capturing is the contrast image capturing, the second MR image capturing is the non-contrast image capturing, and the change recommended condition is the order (before/after) of image capturing with respect to administration of a contrast agent.

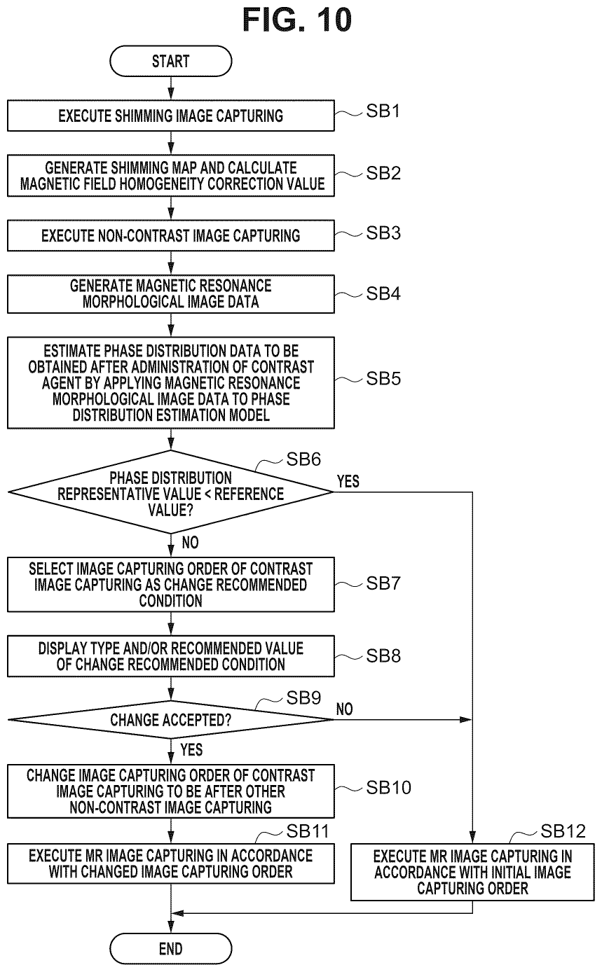

FIG. 10 is a diagram illustrating a typical flow of an MR examination executed by the magnetic resonance imaging apparatus 1 according to the second example. As illustrated in FIG. 10, in step SB1, first, by the image capturing control function 512, the processing circuitry 51 controls the sequence control circuitry 29 and executes shimming image capturing of the subject P. In step SB2, by the reconstruction function 514, the processing circuitry 51 generates a shimming map based on k-space data collected in step SB1, and calculates a magnetic field homogeneity correction value based on the generated shimming map.

After step SB2 is performed, in step SB3, by the image capturing control function 512, the processing circuitry 51 controls the sequence control circuitry 29, and executes the non-contrast image capturing of the subject P. In step SB4, by the reconstruction function 514, the processing circuitry 51 generates magnetic resonance morphological image data based on k-space data collected in step SB3. The non-contrast image capturing in step SB3 is an example of the first MR image capturing.

After step SB4 is performed, in step SB5, by the phase distribution calculation function 515, the processing circuitry 51 estimates phase distribution data to be obtained after administration of a contrast agent by applying the magnetic resonance morphological image data generated in step SB4 to the phase distribution estimation model. The phase distribution estimation model according to the second example is a machine learning model trained to output phase distribution data after contrast agent administration based on input of the magnetic resonance morphological image data without the contrast agent being administered. Hereinafter, the phase distribution estimation model according to the second example will be described. The description of items identical to those of the phase distribution estimation model according to the present embodiment illustrated in FIG. 2 will be omitted.

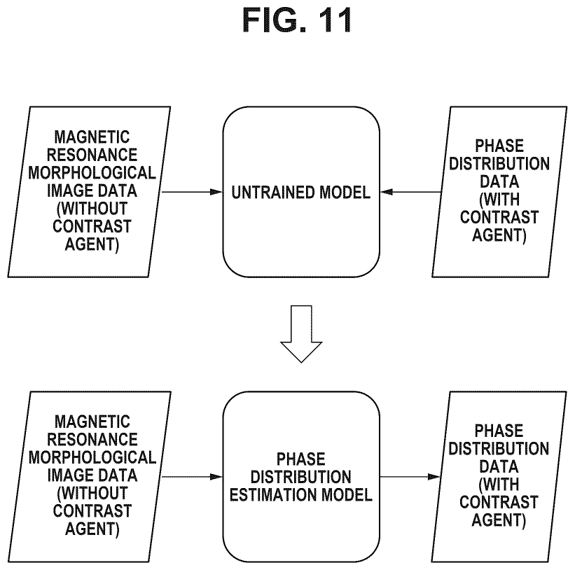

FIG. 11 is a diagram illustrating a generation process of the phase distribution estimation model according to the second example. As illustrated in FIG. 11, the processing circuitry 51 trains an untrained model based on a plurality of training samples including magnetic resonance morphological image data that is input data and phase distribution data that is output data. The magnetic resonance morphological image data is collected by executing MR image capturing of a subject to which a contrast agent has not been administered. As the phase distribution data, a shimming map collected by executing shimming image capturing of a subject after contrast agent administration is used. The phase distribution data is used as ground truth data.

The processing circuitry 51 updates parameters of an untrained model using any optimization algorithm by supervised learning that is based on a plurality of training samples. For example, the processing circuitry 51 generates predicted phase distribution data by performing forward propagation processing on magnetic resonance morphological image data in accordance with the network configuration of the untrained model. Next, the processing circuitry 51 calculates a loss value, which is an error between the predicted phase distribution data and the ground truth phase distribution data, based on a loss function. The processing circuitry 51 updates parameters of the untrained model so that the loss value becomes smaller. The untrained model thereby learns a correlation between the magnetic resonance morphological image data without a contrast agent and the phase distribution data with a contrast agent.

The processing circuitry 51 repeats the generation of the predicted phase distribution data, the calculation of the loss value, and the update of parameters until an end condition is satisfied. A set of parameters when the end condition is satisfied is stored in the memory 53 as optimum parameters. A machine learning model to which the optimum parameters are assigned is used as the phase distribution estimation model according to the second example.

In an operational phase, by applying magnetic resonance morphological image data without a contrast agent administered that is related to a subject to the phase distribution estimation model according to the second example, the processing circuitry 51 estimates phase distribution data after contrast agent administration that is related to the subject. By using the phase distribution estimation model, it becomes possible to estimate the phase distribution data with a contrast agent administered from the magnetic resonance morphological image data without the administration of a contrast agent, without administrating a contrast agent to the subject.

After step SB5 is performed, in step SB6, by the determination function 516, the processing circuitry 51 determines whether a representative value of the phase distribution data estimated in step SB5 is smaller than a reference value. As the representative value of the phase distribution data according to the second example, a statistical value of the phase distribution data is used.

In a case where it is determined in step SB6 that the representative value of the phase distribution data is not smaller than the reference value (NO in step SB6), the processing proceeds to step SB7. In step SB7, by the selection function 517, the processing circuitry 51 selects an image capturing order of contrast image capturing as the change recommended condition. The contrast image capturing is an example of the second MR image capturing. After step SB7 is performed, in step SB8, by the display control function 518, the processing circuitry 51 displays the type and/or the recommended value of the change recommended condition selected in step SB7 on the display 55.

Here, the processing circuitry 51 determines a recommended value of an image capturing order of unexecuted MR image capturing in the MR examination, and displays the recommended value. In a case where the representative value of the phase distribution data is not smaller than the reference value, because the static magnetic field deviation that is caused by administration of a contrast agent is expected to be large, it is desirable to perform the contrast image capturing after the non-contrast image capturing. Accordingly, the processing circuitry 51 rearranges the image capturing order so that unexecuted contrast image capturing is performed after unexecuted non-contrast image capturing. The processing circuitry 51 displays the rearranged image capturing order on the display 55 as a recommended value. The user checks the recommended value and determines whether to accept or reject the change of the image capturing order.

In a case where the change of the change recommended condition is accepted (YES in step SB9), the processing proceeds to step SB10. In step SB10, by the image capturing condition setting function 511, the processing circuitry 51 changes an image capturing order of the contrast image capturing to be after other non-contrast image capturing. The change of the image capturing order may be manually performed by the user via the input interface 57. After step SB10 is performed, in step SB11, by the image capturing control function 512, the processing circuitry 51 executes the MR image capturing in accordance with the changed image capturing order.

On the other hand, in a case where it is determined that the representative value of the phase distribution data is smaller than the reference value (YES in step SB6), the processing proceeds to step SB12. In step SB12, by the image capturing control function 512, the processing circuitry 51 executes the MR image capturing in accordance with an initial image capturing order. In a case where it is determined that the representative value of the phase distribution data is smaller than the reference value, because the static magnetic field deviation that is caused by administration of a contrast agent is expected to be small, it is considered that there is no need to change the order of the contrast image capturing and the non-contrast image capturing. Thus, the MR image capturing may be performed in accordance with the initial image capturing order. Also in a case where the change of the change recommended condition is rejected (NO in step SB9) although it is determined that the representative value of the phase distribution data is not smaller than the reference value (NO in step SB6), the MR image capturing may be performed in accordance with the initial image capturing order.

Accordingly, the MR examination according to the second example is completed.

As described above, according to the second example, in a case where the first MR image capturing is the non-contrast image capturing and the second MR image capturing is the contrast image capturing, it is possible to calculate the phase distribution data after contrast agent administration based on magnetic resonance morphological image data collected by the first MR image capturing, and determine the necessity of a change of the image capturing order of the second MR image capturing based on the phase distribution data. More specifically, before a contrast agent is actually administered to the subject P, it is possible to determine whether to execute the second MR image capturing in accordance with an initial order, or subsequent to the other non-contrast image capturing. With this configuration, it is possible to execute the contrast image capturing and the other non-contrast image capturing at an appropriate timing. In addition, it is possible to reduce an event of re-administration of a contrast agent due to an error in timing of contrast agent administration or the like.

### Third Example

In a third example, the first MR image capturing is the contrast image capturing and the second MR image capturing is the non-contrast image capturing, and the change recommended condition is the image capturing parameter.

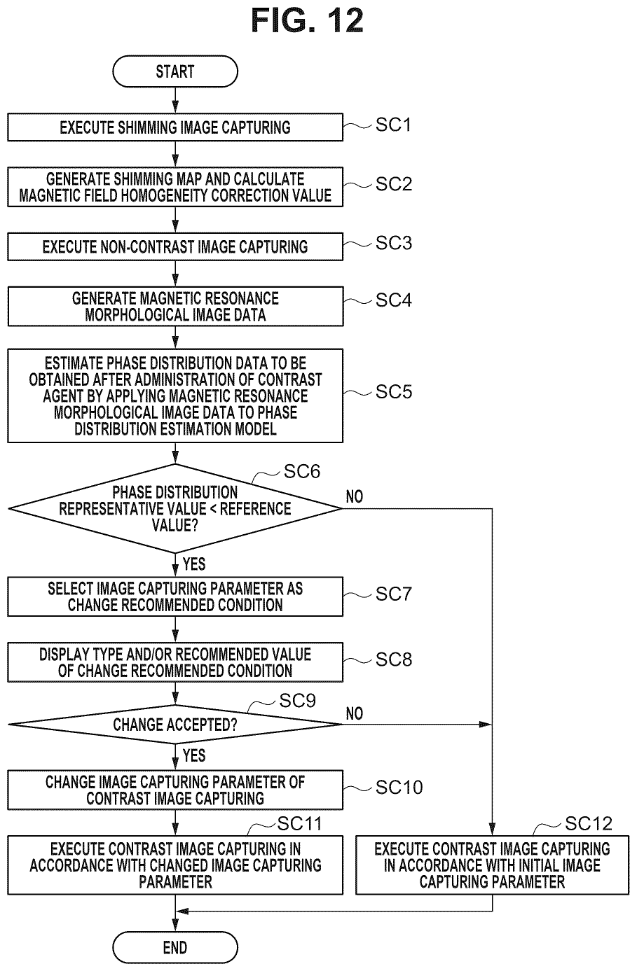

FIG. 12 is a diagram illustrating a typical flow of an MR examination executed by the magnetic resonance imaging apparatus 1 according to the third example. Steps SC1 to SC6 are similar to steps SB1 to SB6 according to the second example.

In a case where it is determined in step SC6 that the representative value of the phase distribution data is not smaller than the reference value (NO in step SC6), the processing proceeds to step SC7. In step SC7, by the selection function 517, the processing circuitry 51 selects an image capturing parameter as the change recommended condition related to contrast image capturing. The contrast image capturing is an example of the second MR image capturing.

The type of the image capturing parameter selectable as the change recommended condition is desirably selected from among a data collection trajectory, a pulse sequence, an echo time, a voxel size, a voxel position, and a water suppression parameter. In a case where the contrast image capturing is the MR image capturing, the type of the image capturing parameter is desirably selected from among a data collection trajectory, a pulse sequence, and an echo time. In a case where the contrast image capturing is the MRS image capturing, the type of the image capturing parameter is desirably selected from a pulse sequence, a voxel size, a voxel position, an echo time, and a water suppression parameter. In a case where the contrast image capturing is the CEST image capturing, the type of the image capturing parameter is desirably selected from a pulse sequence, a voxel size, a voxel position, an echo time, and a water suppression parameter. A method for selecting the type and/or the recommended value of the change recommended condition is as described above.

After step SC7 is performed, in step SC8, by the display control function 518, the processing circuitry 51 displays the type and/or the recommended value of the image capturing parameter selected in step SC7, on the display 55. The user checks the displayed type and/or recommended value of the image capturing parameter, and determines whether to accept or reject the change of the change recommended condition.

In a case where the change of the change recommended condition is accepted (YES in step SC9), the processing proceeds to step SC10. In step SC10, by the image capturing condition setting function 511, the processing circuitry 51 changes the image capturing parameter of the contrast image capturing. After step SC10 is performed, in step SC11, by the image capturing control function 512, the processing circuitry 51 executes the contrast image capturing in accordance with the changed image capturing parameter.

On the other hand, in a case where it is determined that the representative value of the phase distribution data is smaller than the reference value (YES in step SC6), the processing proceeds to step SC12. In step SC12, by the image capturing control function 512, the processing circuitry 51 executes the MR image capturing in accordance with an initial image capturing parameter. In a case where the change of the image capturing parameter is rejected (NO in step SC9) although it is determined that the representative value of the phase distribution data is not smaller than the reference value (NO in step SC6), the MR image capturing may be performed in accordance with the initial image capturing parameter.

Accordingly, the MR examination according to the third example is completed.

As described above, according to the third example, in a case where the first MR image capturing is the non-contrast image capturing and the second MR image capturing is the contrast image capturing, it is possible to calculate the phase distribution data after contrast agent administration based on magnetic resonance morphological image data collected by the first MR image capturing, and determine the necessity of a change of the image capturing parameter of the second MR image capturing based on the phase distribution data. More specifically, before a contrast agent is actually administered to the subject P, it is possible to determine the necessity of a change of the image capturing parameter of the second MR image capturing. Accordingly, it is possible to execute the contrast image capturing with an appropriate image capturing parameter.

According to at least one of the above-described embodiments, it is possible to improve the quality of image capturing data collected by the MR image capturing.

The term “processor” used in the above description means, for example, a CPU, a GPU, or circuitry such as an application specific integrated circuit (ASIC) or a programmable logic device (for example, a simple programmable logic device (SPLD), a complex programmable logic device (CPLD), or a field programmable gate array (FPGA)). The processor implements the function by reading and executing a program stored in storage circuitry. Instead of storing the program in the storage circuitry, the program may be directly incorporated in the circuitry of the processor. In this case, the processor implements the function by reading and executing the program incorporated in the circuitry. On the other hand, when the processor is, for example, an ASIC, the function is directly incorporated as logic circuitry in the circuitry of the processor instead of the program being stored in the storage circuitry. Each processor of the present embodiment is not limited to a case where each processor is configured as a single circuit for each processor, and a plurality of independent circuits may be combined to configure one processor to implement the function thereof. Further, a plurality of components in FIG. 1 may be integrated into one processor to implement the function thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising processing circuitry configured to:
collect k-space data by performing first magnetic resonance (MR) image capturing on a subject;
generate morphological image data representing a morphology of the subject based on the k-space data;
calculate phase distribution data representing a spatial distribution including phase information based on at least the morphological image data; and
determine necessity of a change of second MR image capturing following the first MR image capturing based on the phase distribution data.

2. The magnetic resonance imaging apparatus according to claim 1,
wherein the processing circuitry generates the phase distribution data by applying the morphological image data to a trained model, and
wherein the trained model is a machine learning model trained based on a training sample including morphological image data being input data and phase distribution data being output data.

3. The magnetic resonance imaging apparatus according to claim 2,
wherein the morphological image data is one or more images of a complex image, a magnitude image, and a phase image, and
wherein the phase distribution data is a magnetic field homogeneity map, a susceptibility weighted image, or a quantitative susceptibility mapping image.

4. The magnetic resonance imaging apparatus according to claim 1,
wherein the processing circuitry inputs the morphological image data, medical image data collected by another modality, non-image data described in an electronic medical record, and/or contrast agent information to a trained model to output the phase distribution data, and
wherein the trained model is a machine learning model trained based on a training sample including the morphological image data, the medical image data collected by another modality, the non-image data described in an electronic medical record, and/or the contrast agent information, which are input data, and phase distribution data, which is output data.

5. The magnetic resonance imaging apparatus according to claim 1, wherein, in a case where a representative value of the phase distribution data is less than a reference value, the processing circuitry determines that the second MR image capturing does not need to be changed, and in a case where the representative value is greater than the reference value, the processing circuitry determines that the second MR image capturing needs to be changed.

6. The magnetic resonance imaging apparatus according to claim 5,
wherein, in a case where it is determined that the second MR image capturing needs to be changed, the processing circuitry selects a type and/or a recommended value of a change recommended condition being an image capturing condition affecting a T2 shortening effect, an echo time, and/or a magnetic field homogeneity, and recommended to be changed, among image capturing conditions related to the second MR image capturing, and
wherein the processing circuitry displays the type and/or the recommended value of the change recommended condition on a display device.

7. The magnetic resonance imaging apparatus according to claim 6,
wherein the processing circuitry is further configured to change a value of the change recommended condition in a case where it is determined that the second MR image capturing needs to be changed, and
wherein the processing circuitry performs the second MR image capturing on the subject in accordance with a changed value of the change recommended condition.

8. The magnetic resonance imaging apparatus according to claim 6, wherein the processing circuitry selects, as the change recommended condition, an image capturing position, a magnetic field homogeneity correction value, an order (before/after) of image capturing with respect to administration of a contrast agent, a data collection trajectory, a pulse sequence, an echo time, a voxel size, a voxel position, and/or a water suppression parameter.

9. The magnetic resonance imaging apparatus according to claim 6,
wherein the change recommended condition is an image capturing parameter including a data collection trajectory, a pulse sequence, an echo time, a voxel size, a voxel position, and/or a water suppression parameter, and
wherein the processing circuitry determines whether each value of an image capturing parameter of the second MR image capturing satisfies a condition related to a T2 shortening effect, an echo time, and/or a magnetic field homogeneity, and selects an image capturing parameter including a value not satisfying the condition as the change recommended condition.

10. The magnetic resonance imaging apparatus according to claim 8,
wherein the first MR image capturing and the second MR image capturing are image capturing in which a contrast agent is not used,
wherein the processing circuitry selects the image capturing position and/or the magnetic field homogeneity correction value as the change recommended condition, and
wherein the processing circuitry changes a value of the change recommended condition.

11. The magnetic resonance imaging apparatus according to claim 8,
wherein the first MR image capturing is image capturing in which a contrast agent is not used,
wherein the second MR image capturing is image capturing in which a contrast agent is used,
wherein the processing circuitry selects the order (before/after) of image capturing with respect to administration of a contrast agent as the change recommended condition, and
wherein the processing circuitry rearranges an order of the second MR image capturing and other MR image capturing in which a contrast agent is not used so that the second MR image capturing is executed after the other MR image capturing.

12. The magnetic resonance imaging apparatus according to claim 8,
wherein the first MR image capturing is image capturing in which a contrast agent is not used,
wherein the second MR image capturing is image capturing in which a contrast agent is used,
wherein the processing circuitry selects the data collection trajectory, the pulse sequence, the echo time, the voxel size, the voxel position, and/or the water suppression parameter as the change recommended condition, and
wherein the processing circuitry changes a value of the change recommended condition.

13. The magnetic resonance imaging apparatus according to claim 5, wherein the processing circuitry calculates the representative value based on a data value of the phase distribution data or a difference value between the data value of the phase distribution data and a data value of a shimming map collected by shimming image capturing executed before or after the first MR image capturing.

14. The magnetic resonance imaging apparatus according to claim 1, wherein the processing circuitry estimates the phase distribution data related to the subject to which a contrast agent has been administered based on the morphological image data related to the subject to which a contrast agent has not been administered.

15. The magnetic resonance imaging apparatus according to claim 1, wherein the second MR image capturing is image capturing for image collection or image capturing for spectrum collection.

16. The magnetic resonance imaging apparatus according to claim 1, wherein a spatial range of the phase distribution data is an image capturing target region in a case of MR image capturing, and inside of volume of interest (VOI), or the inside of the VOI and a surrounding region of the VOI in a case of MRS image capturing.

17. A magnetic resonance image capturing support method comprising:
acquiring morphological image data representing a morphology of a subject having been obtained by first MR image capturing on the subject;
calculating phase distribution data representing a spatial distribution of a phase of a static magnetic field based on at least the morphological image data; and
determining necessity of a change of second MR image capturing following the first MR image capturing based on the phase distribution data.
